(19) United States
(12) Patent Application Publication
(10) Pub. No.: US 2011/0108845 A1
(43) Pub. Date: May 12, 2011

(54) DISPLAY DEVICE

(75) Inventors: Do-Hyun KWON, Yongin-city (KR); Il-Jeong Lee, Yongin-city (KR); Choong-Youl Im, Yongin-city (KR); Young-Dae Kim, Yongin-city (KR); Jong-Mo Yeo, Yongin-city (KR); Ju-Won Yoon, Yongin-city (KR); Chool-Ho Yu, Yongin-city (KR)

(73) Assignee: Samsung Mobile Display Co., Ltd., Yongin-city (KR)

(21) Appl. No.: 12/712,470

(22) Filed: Feb. 25, 2010

(30) Foreign Application Priority Data
Nov. 12, 2009 (KR) 10-2009-0109161

(51) Int. Cl. H01L 33/58; H01L 33/16

(52) U.S. Cl. 257/72; 438/29; 257/E33.055; 257/E33.053

(57) ABSTRACT

In a display device, the display device includes a substrate, a red color filter layer, a green color filter layer, and a blue color filter layer. The substrate has red, green and blue sub-pixel regions. The red color filter layer is located on the red, green and blue sub-pixel regions, and has a first opening formed in the green sub-pixel region and a second opening formed in the blue sub-pixel region. The green color filter layer is located in the first opening. The blue color filter layer is located in the second opening. Since the red color filter layer is used as an interlayer insulating layer, there is no need to perform a separate process to form a color filter layer and a process for an interlayer insulating layer can be omitted. Thus, it can simplify a process.

### CROSS-REFERENCE TO RELATED APPLICATION

This application claims the benefit of Korean Patent Application No. 10-2009-0109161, filed Nov. 12, 2009 in the Korean Intellectual Property Office, the disclosure of which is incorporated herein by reference.

### BACKGROUND

1. Field

Non-limiting example embodiments of the present invention relate to a display device, and more particularly, to a display device that can display images.

2. Description of the Related Art

Among flat panel display devices, an organic light emitting diode (OLED) display device has attracted attention as a next generation flat panel display device since it provides self emission, a wide viewing angle, a fast response speed, a small thickness, relatively low production costs, and high contrast. In general, such an OLED display device includes a substrate, an anode located on the substrate, an emission layer located on the anode, and a cathode located on the emission layer. In the OLED display device, when a voltage is applied between the anode and the cathode, holes and electrons may be injected into the emission layer, and recombined in the emission layer, thereby generating excitons. The OLED display device emits light using energy generated when the excitons transition from an excited state to a ground state.

To implement a full-color OLED display device, emission layers may be formed corresponding to red (R), green (G) and blue (B) light, respectively. However, in this case, the emission layers corresponding to the R, G and B light have different lifespan characteristics. Thus it is difficult to maintain a white balance when the OLED display device is driven for a long time. To solve this problem, an emission layer is formed to emit a single color of light, and a color filter or color conversion layer is used. The color filter extracts light corresponding to a predetermined color from the light emitted from the emission layer. The color conversion layer changes the light emitted from the emission layer into a predetermined color of light.

FIG. 1 is a cross-sectional view of a conventional bottom-emission OLED display device having a color filter layer. Referring to FIG. 1, the bottom-emission OLED display device includes a color filter layer 11(R), 11(G) and 11(B) formed on a transparent substrate 10. A passivation layer 12 is formed on the color filter layer 11(R), 11(G) and 11(B) on the entire surface of the substrate 10. Subsequently, a transparent electrode layer 13 is patterned and formed on the passivation layer 12 to correspond to the color filter layer 11(R), 11(G) and 11(B). A hole transport layer 14, an emission layer 15, an electron injection layer 16 and a bottom electrode layer 17 may be formed on the transparent electrode layer 13. Here, the hole transport layer 14, the emission layer 15 and the electron injection layer 15 (i.e. all but the bottom electrode layer 17) may be organic thin films. However, since the bottom-emission OLED display device having the color filter layer 11(R), 11(G) and 11(B) needs a separate process to form the color filter layer 11(R), 11(G) and 11(B) on the lower substrate 10, the process may be complicated.

### SUMMARY

Non-limiting example embodiments of the present invention provide a display device which includes a color filter layer and thus has a simple process.

According to non-limiting example embodiments of the present invention, a display device includes: a substrate having a red sub-pixel region, a green sub-pixel region and a blue sub-pixel region; a red color filter layer located on the red, green and blue sub-pixel regions and having a first opening formed in the green sub-pixel region and a second opening formed in the blue sub-pixel region; a green color filter layer located in the first opening; and a blue color filter layer disposed in the second opening.

Additional advantages of the non-limiting example embodiments of the present invention will be set forth in part in the description which follows and, in part, will be obvious from the description, or may be learned by practice of the present invention.

### BRIEF DESCRIPTION OF THE DRAWINGS

These and/or other advantages of the present invention will become apparent and more readily appreciated from the following description of the non-limiting example embodiments, taken in conjunction with the accompanying drawings of which:

FIG. 1 is a cross-sectional view of a conventional bottom-emission OLED display device having a color filter layer;

FIGS. 2A through 2G are cross-sectional views illustrating a display device and a method of fabricating the same according to non-limiting example embodiments of the present invention;

FIG. 3 is a cross-sectional view of a display device according to non-limiting example embodiments of the present invention; and

FIG. 4 is graphs showing changes in optical efficiency of an anode electrode by wavelength.

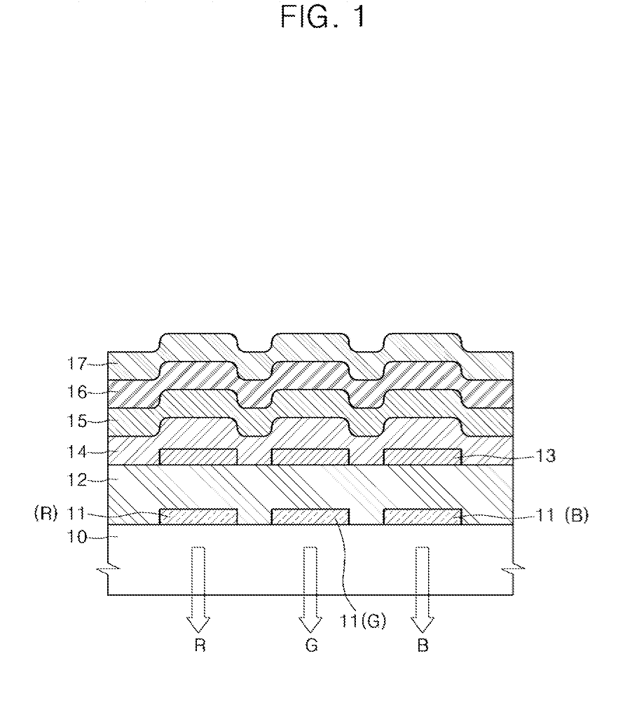

### DETAILED DESCRIPTION

Reference will now be made in detail to the present non-limiting example embodiments of the present invention, examples of which may be illustrated in the accompanying drawings, wherein like reference numerals refer to the like elements throughout. The non-limiting example embodiments may be described below in order to explain the present invention by referring to the figures.

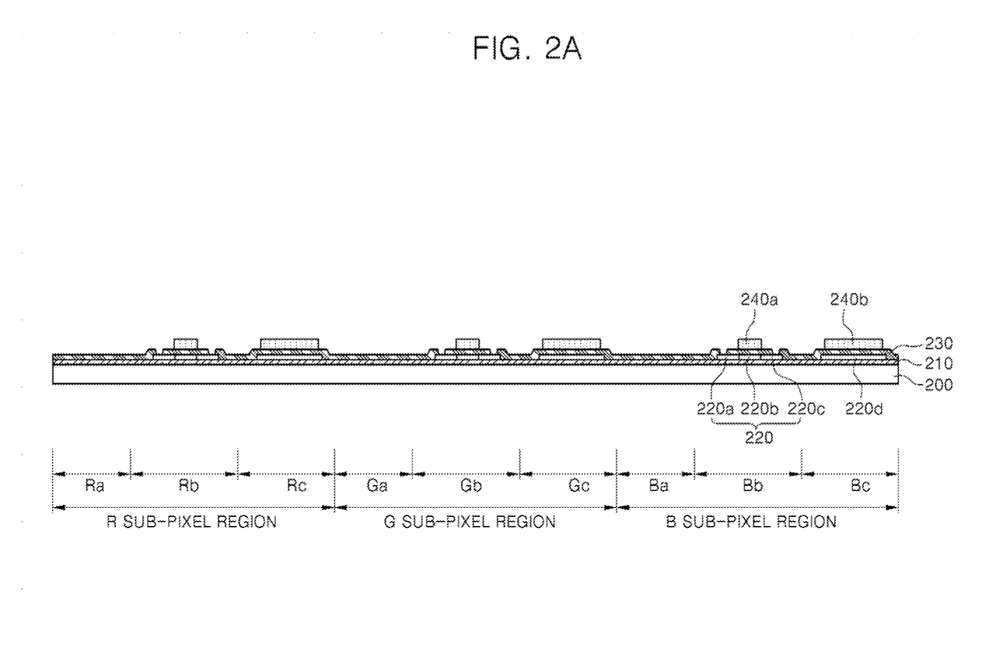

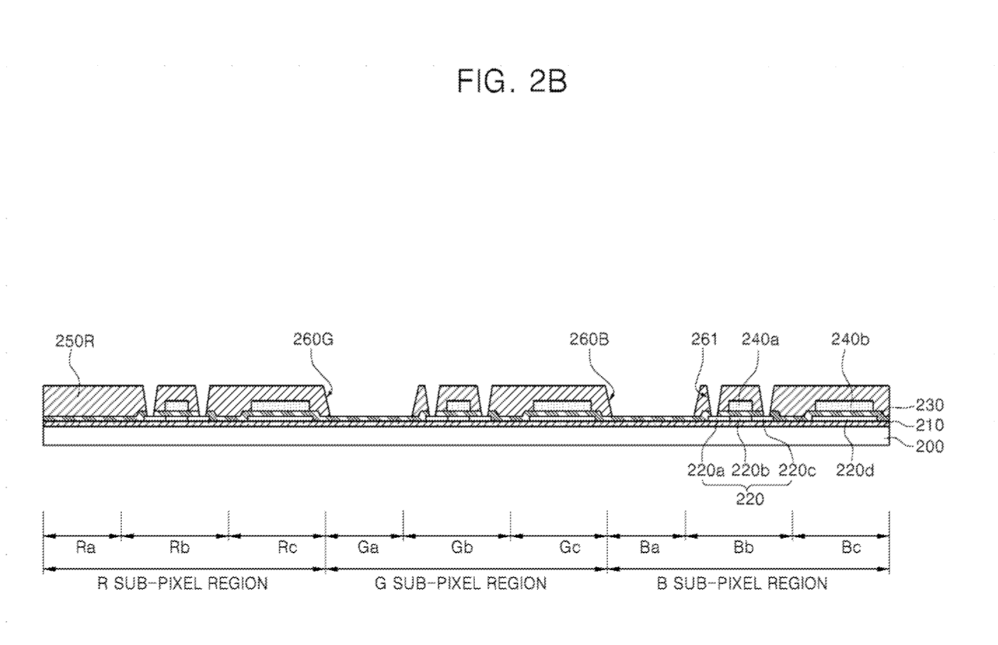

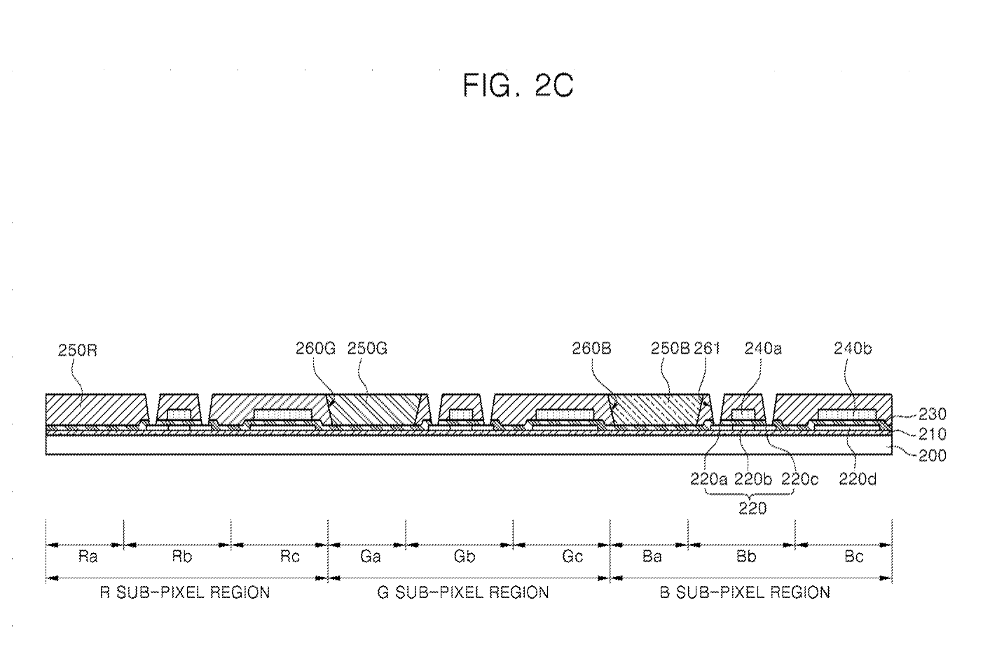

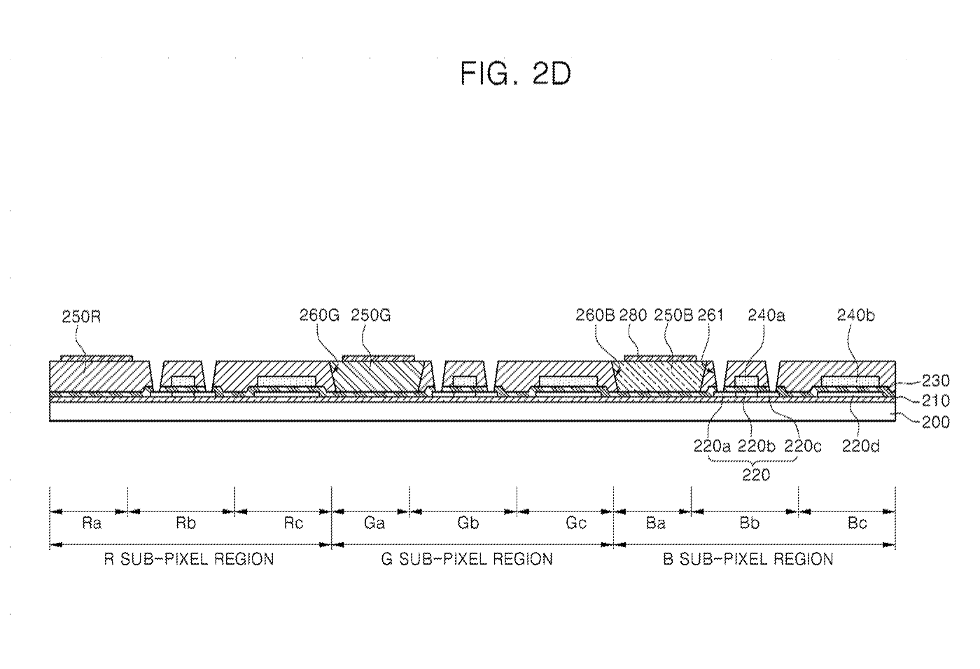

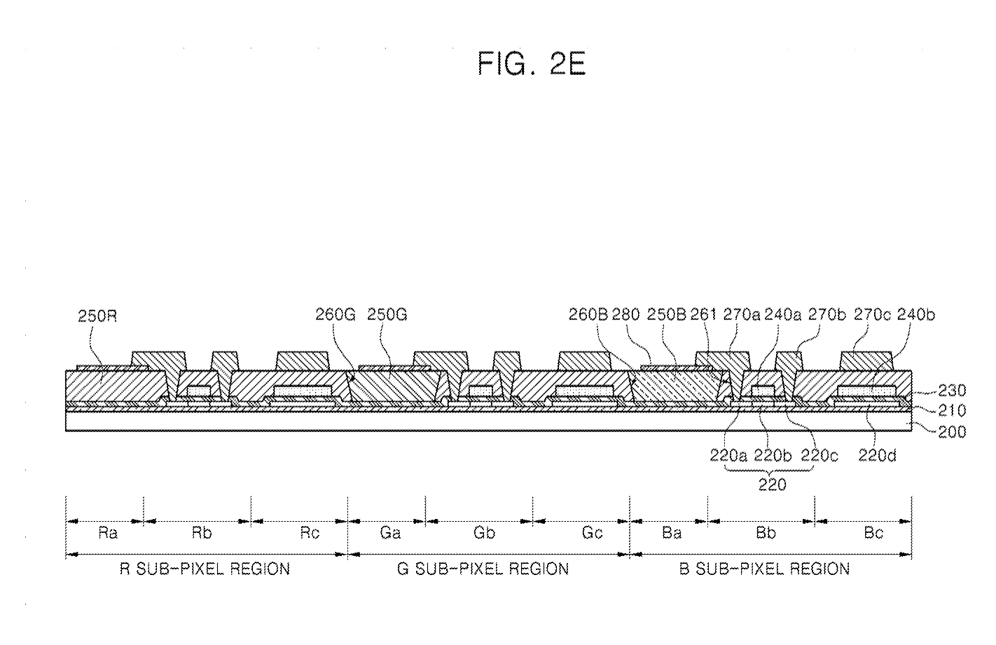

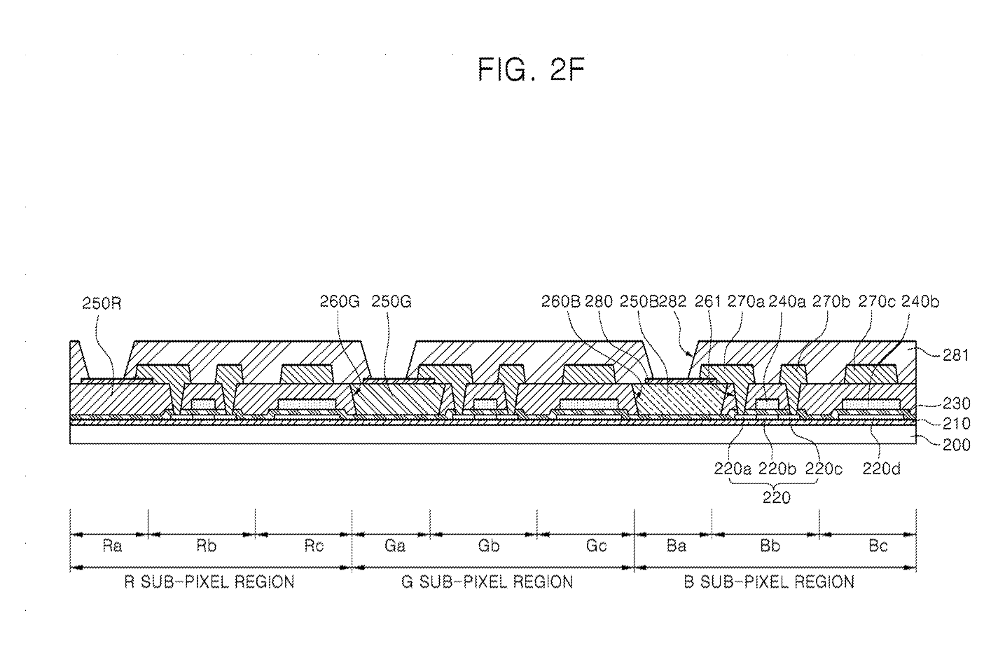

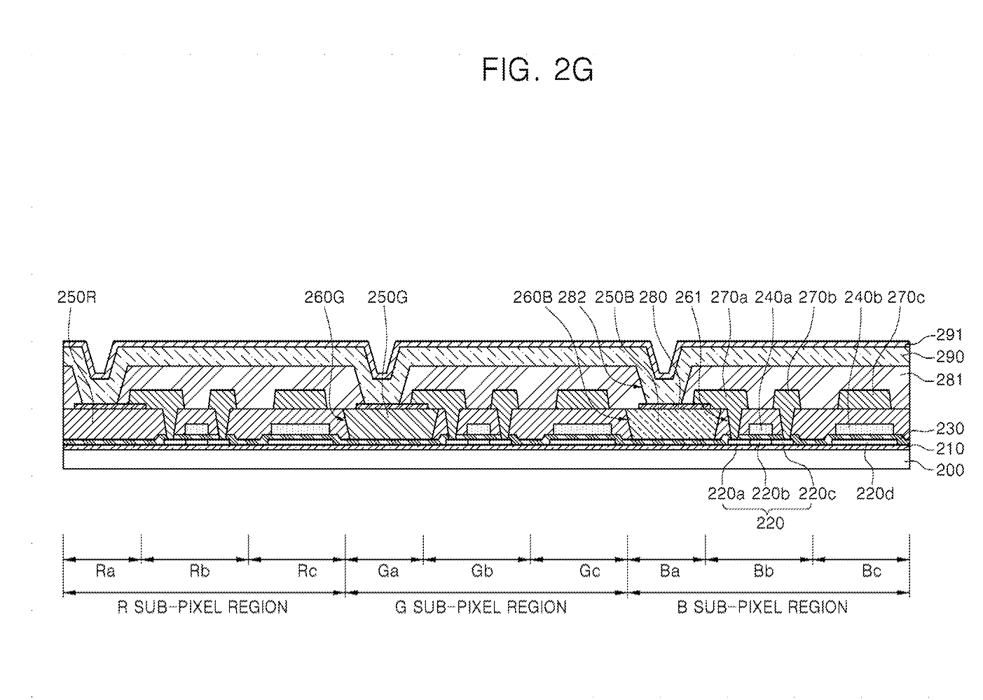

FIGS. 2A through 2G are cross-sectional views illustrating a display device and a method of fabricating the same according to non-limiting example embodiments of the present invention. The example of the display device shown in FIGS. 2A through 2G is a bottom-emission OLED display device having a color filter layer. However, the non-limiting example embodiments of the present invention may be applied to all kinds of display devices including the OLED display device and a liquid crystal display (LCD) device.

Referring to FIG. 2A, a buffer layer 210 may be formed on a transparent insulating substrate 200. The substrate 200 may be formed using glass or plastic but the non-example embodiment of the present invention may not be limited thereto. The substrate 200 may include a red (R) sub-pixel region, a green (G) sub-pixel region, and a blue (B) sub-pixel region.

Here, each of the red (R) sub-pixel region, the green (G) sub-pixel region and the blue (B) sub-pixel region may include a light extraction region Ra, Ga, Ba, a transistor region Rb, Gb, Bb and a capacitor region Rc, Gc, Bc. The buffer layer 210 serves to prevent diffusion of moisture or impurities generated from the substrate 200.

Subsequently, an amorphous silicon layer (not shown) may be deposited on the buffer layer 210, and may be crystallized by excimer laser annealing (ELA), sequential lateral solidification (SLS), metal induced crystallization (MIC) or metal induced lateral crystallization (MILC). The crystallized silicon layer may be patterned by photolithography and etching, thereby forming a polycrystalline silicon pattern forming a semiconductor layer 220 and electrode 220d in the transistor region Rb, Gb, Bb and the capacitor region Rc, Gc, Bc of each sub-pixel region R, B, G.

A gate insulating layer 230 may be formed on the entire surface of the substrate 200 above the buffer layer 210 and the formed polycrystalline silicon pattern. Here, the gate insulating layer 230 may be formed using a silicon oxide layer, a silicon nitride layer or a stacked layer thereof. The layer 230 can be formed by plasma-enhanced chemical vapor deposition (PECVD) or low-pressure chemical vapor deposition (LPCVD).

Subsequently, a gate electrode material layer (not shown) may be formed on the gate insulating layer 230 and etched by photolithography and/or etching, thereby forming a gate electrode 240a and a second capacitor electrode 240b. The gate electrode 240a may be formed corresponding to a channel region 220b to be described later in the transistor region Rb, Gb, Bb of each sub-pixel region. The second capacitor electrode 240b may be formed in the capacitor region Rc, Gc, Bc of each sub-pixel region R, G, B.

By way of example, the gate electrode material layer may be formed using molybdenum (Mo), tungsten (W), tungsten-molybdenum (MoW), tungsten silicide (WSi₂), molybdenum silicide (MoSi₂), aluminum (Al), etc. These materials may be independently used or mixed with one another. The gate electrode material layer may be formed by sputtering or vacuum deposition.

Subsequently, impurities may be injected into the semiconductor layer 220 using the gate electrode 240a and the second capacitor electrode 240b as a mask, thereby forming in the semiconductor layer 220 source and drain regions 220a and 220c and a channel region 220b in the transistor region Rb, Gb, Bb of each sub-pixel region, and a first capacitor electrode 220d in the capacitor region Rc, Gc, Bc of each sub-pixel region R, G, B. As shown, the first capacitor electrode 220d, the gate insulating layer 230 and the second capacitor electrode 240b may constitute a lower capacitor.

The impurities may be one selected from n-type and p-type impurities. The n-type impurities may be phosphorous (P), arsenic (As), bismuth (Bi), antimony (Sb), or a combination thereof. The p-type impurities may be boron (B), boron fluoride (BF), aluminum (Al), gallium (Ga), titanium (Ti), indium (In) or a combination thereof. However, the present invention may not be limited thereto.

Referring to FIG. 2B, a red color filter layer 250R may be formed on the entire surface of the substrate 200 above the gate electrode 240a and the second capacitor electrode 240b of the sub-pixel regions R, G, B. The formed red color filter layer 250R serves as an interlayer insulating layer. For example, the red color filter layer 250R may be formed in a subsequent process along with the transistor, and serve as an insulating layer with respect to a first electrode (i.e., an anode electrode in each region R, G, B). In other words, the red color filter layer 250R may cover the transistor in each region R, G, B. Specifically, the red color filter layer 250R may cover the gate electrode 240a, which may be located on the uppermost portion of the transistor. The first electrode (i.e., an anode electrode) (not shown) may be located on the red color filter layer 250R, and thus insulated from the transistor.

Referring again to FIG. 2B, contact holes 261 exposing the source and drain regions 220a and 220c may be formed through the red color filter layer 250R and the gate insulating layer 230. While the contact holes 261 may be formed, an opening 260G may be formed in a light extraction region Ga of the green (G) sub-pixel region, and an opening 260B located in a light extraction region Ba of the blue (B) sub-pixel region may be formed in the red color filter layer 250R. However, it may be understood that the openings 260G and 260B need not be formed while the contact holes 261 may be formed.

Referring to FIG. 2C, a green color filter layer 250G may be formed in the opening 260G located in the light extraction region Ga of the green (G) sub-pixel region. A blue color filter layer 250B may be formed the opening 260B located in the light extraction region Ba of the blue (B) sub-pixel region.

Here, each of the color filter layers 250R, 250G and 250B may include an acrylic resin as a support, a pigment, and a polymer binder. The color filter layers 250R, 250G and 250B may also include a functional monomer. Here, according to the kind of the pigment exhibiting a color, the color filter layers 250R, 250G and 250B may be classified into the red color filter layer 250R, the green color filter layer 250G, and the blue color filter layer 250B.

The red color filter layer 250R, the green color filter layer 250G and the blue color filter layer 250B transmit light emitted from an emission layer formed in a subsequent process to have wavelengths in red, green and blue regions, respectively.

The polymer binder may protect a liquid monomer from a developing solution at room temperature, and may influence the stability of pigment dispersion. The polymer binder may further influence the reliability of RGB patterns such as heat resistance and light resistance. The pigment may be an organic particle having excellent resistances to light and heat, which scatters light. As the particle may become relatively smaller, the pigment has relatively higher transparency and may have a more excellent dispersion characteristic.

Meanwhile, in the shown example, each of the color filter layers 250R, 250G and 250B may be formed to a thickness of about 1.0 to 2.5 μm. When the thickness of the color filter layer may be less than about 1.0 μm, color purity may decrease, and when the thickness of the color filter layer may be more than about 2.5 μm, the transparency may decrease, and a crystal of the pigment may be extracted or the color filter layer or a color filter may have a crack.

Each of the color filter layers 250R, 250G and 250B may be formed by pigment dispersion or dying, but the present invention may not be limited thereto. Each of the color filter layers 250R, 250G and 250B may be formed during a process of fabricating a transistor, and may serve as an interlayer insulating layer. For this reason, a separate process of forming a color filter layer may not be needed, and a process for an interlayer insulating layer can be omitted, thereby simplifying the process.

As described above, the red color filter layer 250R may be used as an interlayer insulating layer. The opening 260G for defining the light extraction region Ga of the green (G) sub-pixel region and the opening 260B for defining the light extraction region Ba of the blue (B) sub-pixel region may be formed in the red color filter layer 250R, and the green color filter layer 250G and the blue color filter layer 250B may be formed in the openings 260G and 260B, respectively. The reason why the red color filter layer 250R may be used as an interlayer insulating layer may be that the red color filter layer 250R may be the least damaged by plasma used in an etching process of the gate insulating layer 230 as compared to the materials used in the other color filter layers 250B, 250G. Specifically, to form the contact holes 261 exposing the source and drain regions 220a and 220c in the gate insulating layer 230, a dry etching process may be performed using the color filter layer 250R as a mask. Accordingly, a surface of the color filter layer 250R may be damaged by plasma used in the dry etching process. Here, since the red color filter layer 250R as compared to the green and blue color filter layers 250B, 250G may be the least damaged by the plasma, the red color filter layer 250R may be used as an interlayer insulating layer and the green and blue color filter layers 250B, 250G may be formed after the dry etching process may be performed.

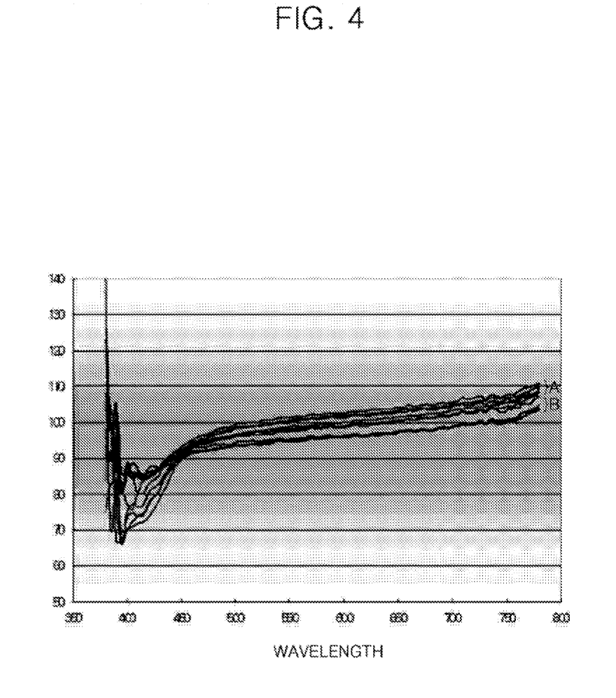

FIG. 4 is graphs showing changes in optical efficiency of a first electrode (that is, an anode electrode) by wavelength. Here, the X axis denotes a wavelength, and the Y axis denotes a relative size. Graph A is a graph when a color filter layer may be used as an interlayer insulating layer, and graph B is a graph when a general organic layer may be used as an interlayer insulating layer. Referring to FIG. 4, in graph B using the general organic layer as the interlayer insulating layer, it can be seen that there may be no significant change in optical efficiency by wavelength. However, according to the non-limiting example embodiments of the present invention shown in graph A, there may be a great change in optical efficiency by wavelength when a color filter layer (such as color filter 250R) may be used as an interlayer insulating layer.

Specifically, it can be seen that, when the color filter layer may be used as the interlayer insulating layer, the optical efficiency may be lower in a short wavelength range (e.g., at about 450 nm or lower), than when the general organic layer may be used as the interlayer insulating layer. In addition, as the wavelength may become longer, it can be seen that, when the color filter layer may be used as the interlayer insulating layer, the optical efficiency may be substantially equal to or relatively higher than when the general organic layer may be used as the interlayer insulating layer.

In other words, when the color filter layer may be used as the interlayer insulating layer, even though it may be damaged by plasma, it can be seen that the optical efficiency may be relatively low at short wavelengths, whereas, the optical efficiency may be substantially equal or relatively higher than the general organic layer at long wavelengths. Thus, among the red, green and blue color filter layers 250R, 250B, 250G, the non-limiting example embodiments of the present invention use the red color filter layer 250R that may be the least damaged by plasma due to it having the longest wavelength range. However, while shown as using the red color filter layer 250R as being least damaged by the plasma, it may be understood that others of the color layers 250B, 250G can be used as the interlayer insulating layer instead of or in addition to the red color filter layer 250R and still be acceptable relative to the general organic layer.

Subsequently, referring to FIG. 2D, a first electrode material may be formed above the color filter layers 250R, 250G, 250B on the entire surface of the substrate 200 and patterned, thereby forming a first electrode 280 (i.e., an anode electrode) in a light extraction region Ra, Ga or Bb of each sub-pixel region R, G, B. The shown non-limiting example embodiment of the present invention relates to a bottom-emission structure, and the first electrode 280 may be a transparent electrode, for example, formed using indium tin oxide (ITO) or indium zinc oxide (IZO).

The first electrode 280 may be formed by sputtering, ion plating or evaporation, and then patterned by wet etching to be selectively removed using a pattern such as a photo resist (PR) formed by photolithography after deposition. The wet etching process patterning the first electrode 280 may prevent damage to a color filter layer 250R, 250G, 250B using an etchant having a relatively high etch rate between the first electrode 280 and the color filter layers 250R, 250G, 250B.

The first electrode 280 may be formed on the red color filter layer 280R used as an interlayer insulating layer in the red (R) sub-pixel region. The first electrode 280 may be formed on the green color filter layer 250G formed in an opening 260G of the red color filter layer 250R in the green (G) sub-pixel region. The first electrode 280 may be formed on the blue color filter layer 250B formed in the opening 260B of the red color filter layer 250R in the blue (B) sub-pixel region.

Referring to FIG. 2E, a metal layer may be stacked on the red color filter layer 250R, 250G, 250B including the source and drain regions 220a and 220c exposed through the contact holes 261 and the first electrode 280, and patterned, thereby forming source and drain electrodes 270a and 270b in the through holes 261. The source and drain electrodes 270a and 270b may be electrically connected through the contact holes 261 with the respective source and drain regions 220a and 220c. The first electrode 280 may be electrically connected to the source electrode 270a.

While the source and drain electrodes 270a and 270b may be formed, a third capacitor electrode 270c may be formed in the capacitor region Rc, Gc, Bc of each sub-pixel region R, G, B. Here, the second capacitor electrode 240b, the red color filter layer 250R and the third capacitor electrode 270c constitute an upper capacitor. However, it may be understood that the third capacitor 270c can be otherwise formed.

Here, the metal layer used to form the electrodes 270a, 270b, 270c can be a single layer of molybdenum (Mo), a molybdenum-tungsten (MoW) alloy, aluminum or an aluminum-neodymium (Nd) alloy, or a stacked layer thereof.

FIGS. 2D and 2E, while the source and drain electrodes 270a and 270b electrically connected with the first electrode 280 may be formed after the first electrode 280 may be formed, the first electrode 280 may be formed to be electrically connected with the source and drain electrodes 270a and 270b after the source and drain electrodes 270a and 270b may be formed.

As described above, the semiconductor layer 220, the gate electrode 240a and the source and drain electrodes 270a and 270b constitute a transistor, which may be formed in the transistor region Rb, Gb, Bb as described above. Here, the transistor may employ the red color filter layer 250R as the interlayer insulating layer to electrically insulate the gate electrode 240a from the source and drain electrodes 270a and 270b.

Subsequently, referring to FIG. 2F, a pixel defining layer material may be formed on the entire surface of the substrate 200 above the source and drain electrodes 270a and 270b and the first electrode 280, and patterned. The patterned pixel defining layer material forms a pixel defining layer 281 and an opening 282 exposing a part of a surface of the first electrode 280 for each region R, G, B. The pixel defining layer 281 may generally include an organic material, such as polyimide (PI), polyamide (PA), acryl resin, benzo cyclo butane (BCB) or phenolic resin. These materials may be independently used or mixed with one another. Here, the pixel defining layer 281 may be formed by spin coating.

Subsequently, referring FIG. 2G, an emission layer 290 may be formed on the substrate including the exposed first electrode 280. The emission layer 290 may be formed to emit a single color of light, for example, white or blue light. The emission layer 290 may emit white light by adding emitting materials exhibiting different colors and a dopant or mixing polybutadiene (PBD), tetraphenylborate (TPB), Coumarin 6, DCM 1 and nile red with a polymer such as polyvinylcabazole (PVK) in an appropriate ratio. However, the present invention may not be limited thereto.

A white light emitting material for the emission layer 290 may be obtained by mixing two different color emitting materials with each other and adding other light emitting materials thereto. For example, after a red light emitting material may be mixed with a green light emitting material, a blue light emitting material may be added thereto, and thus a white light emitting material may be obtained. The red light emitting material may be formed using BSA-2 (i.e., a relatively low molecular weight material), polythiophene (PT) (i.e., a high molecular weight material), or a derivative thereof. These materials may be independently used or mixed with each other. The green light emitting material may be formed using relatively low molecular weight materials such as Alq₃, bis(benzoquinoline)beryllium (BeBq₂) and tris(4-methyl-8-quinolinolate)aluminum (Almq), high molecular weight materials such as poly(p-phenylenevinylene) (PPV) and derivatives thereof. The blue light emitting material may be formed using a relatively low molecular weight material such as ZnPBO, Bis(2-methyl-8-quinolinolato-N1,O8)-(1,1-biphenyl-4-olato)aluminum (Balq), 4,4′-bis(2,2′-diphenylvnyl)-1,1′-biphenyl) (DPVBi), or OXA-D, a high molecular weight material such as polyphenylene (PPP), or a derivative thereof. These materials may be independently used or mixed with one another.

The organic emission layer 290 may include a hole transporting compound, an electron transporting compound or a mixture thereof as a host material, and serves to inject holes and electrons, transport holes and electrons, or generate excitons by recombination of holes and electrons. The organic emission layer 290 may also include a compound which may be relatively electrically neutral. The hole transporting compound used as the host material of the organic emission layer may be formed using a triazole derivative, an imidazole derivative, a phenyldiamine derivative, arylamine derivative or an aromatic tertiary amine, and preferably, a tetraarylbenzidine compound (triaryldiamine or triphenyldiamine (TPD)) of a triphenyldiamine derivative. The electron transporting compound used as the host material of the organic emission layer may be formed using tris(8-quinolinato) aluminum (Alq₃).

The organic emission layer 290 has a structure in which the host material such as the hole transporting compound, the electron transporting compound or a combination thereof may be doped with a dopant such as a fluorescent material. In the non-limiting example embodiments of the present invention, a rubrene-based compound, a coumarine-based compound, a quinacridone-based compound or a dicyanomethylpyran-based compound may be used. These materials may be independently used or mixed with each other as the fluorescent material contained as a dopant. By adding a small amount of the dopant, emission efficiency and endurance may be improved. The emission layer 290 may be stacked by vacuum deposition or spin coating.

Meanwhile, when the emission layer 290 emits blue light, a color conversion layer may be formed instead of the color filter layer 250R, 250G, 250B. In other words, when the emission layer 290 emits blue light, the red color filter layer 250R may be replaced with a red color conversion layer, the green color filer layer 250G with a green conversion layer, and the blue color filter layer 250B with a blue color conversion layer.

The color conversion layer may include a fluorescent material and a polymer binder. The fluorescent material emits light with a longer wavelength than incident light when the fluorescent material may be excited due to the light entering from the emission layer and then transitions to a ground state. The color conversion layers may be classified as a red color conversion layer converting the incident light into red light, a green color conversion layer converting the incident light into green light, and a blue color conversion layer converting the incident light into blue light according to the kind of the fluorescent material. The color conversion layers may be formed by pigment dispersion or dying, but may not be limited thereto. The color conversion layer may be formed by pigment dispersion in which exposure and development may be repeatedly performed.

Subsequently, referring to FIG. 2G, a second electrode 291 may be formed on the emission layer 290. As described above, the present shown non-limiting example embodiment of the present invention relates to the bottom emission structure, so that the second electrode 291 may be formed using magnesium (Mg), calcium (Ca), aluminum (Al), silver (Ag) or an alloy thereof. These materials may be independently used or mixed with one another. However, the present invention may not be limited thereto.

Subsequently, the substrate 200 having the second electrode 291 may be attached to an upper substrate (not shown) to be encapsulated by a common method, and thus a bottom-emission active matrix OLED display device may be completed.

To drive such an OLED display device, the emission layer 290 may emit white light toward the substrate 200. The white light emitted from the emission layer 390 may be extracted to the outside through the first electrode 280, which may be a transparent electrode, and the transparent substrate 200. Here, the color filter layers 250R, 250G and 250B may be located in the light extraction region Ra, Ga, Ba of each sub-pixel region R, G, B, which may be a path through which the light extracted from the white emission layer 290 to the outside passes. The white light may be extracted to the outside through the corresponding red, green and blue color filter layers 250R, 250G and 250B, thereby implementing a full-color OLED display device, which may be capable of emitting red (R), green (G) and blue (B) light.

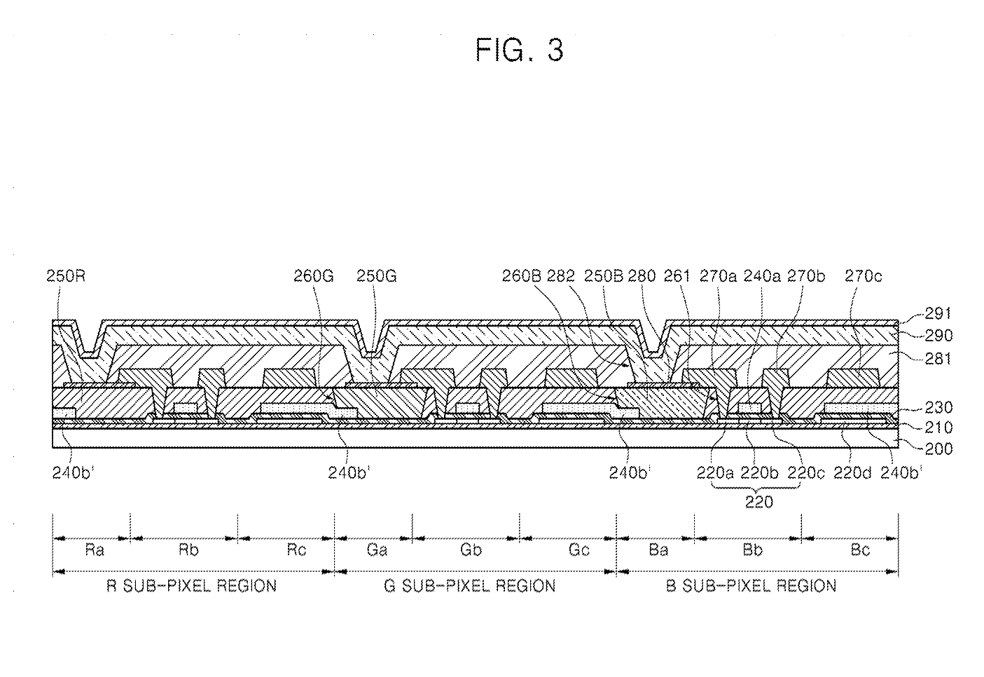

FIG. 3 is a cross-sectional view of a display device according to non-limiting example embodiments of the present invention. The display device shown in FIG. 3 may be a bottom-emission OLED display device having a color filter layer 250R, 250G, 250B. However, the present non-limiting example embodiments may be applied to all kinds of display devices including the OLED display device and an LCD device.

Referring to FIG. 3, the OLED display device may be formed by extending a second capacitor electrode 240b′ from the capacitor region Rc, Gc, Bc to a predetermined region of a light extraction region Ra, Gb, Bc of each sub-pixel region R, G, B. The second capacitor electrode 240b′ may be formed by forming and patterning a gate electrode material layer. However, unlike the non-limiting example embodiments described with reference to FIGS. 2A through 2G, the second capacitor electrode 240b′ may be formed to extend to a predetermined region of the light extraction region Rc, Ga, Bc of each sub-pixel region R, G, B. Thus, the second capacitor electrode 240b′ may be used as a black matrix.

To be specific, the OLED display device formed in a general structure may have a separately-formed black matrix, which may be formed using a chromium oxide (CrOx) layer and a chromium (Cr) layer, in a region excluding a portion corresponding to a pixel electrode of a substrate in order to block reflective light having a bad influence on displaying images. However, in the present non-limiting example embodiments, the second capacitor electrode 240b′ may be used as a black matrix by being extended to a predetermined region of the light extracting region. Thus, the second capacitor electrode 240b′ can block reflective light in a region excluding the light extraction region and inhibit a light leak current of a transistor.

Consequently, since a red color filter layer may be used as an interlayer insulating layer to electrically insulate a gate electrode from source and drain electrodes, the present invention does not need a separate process to form a color filter layer and a process for an interlayer insulating layer, and thus can have a simple process.

Although the present invention has been described with reference to predetermined non-limiting example embodiments thereof, it will be understood by those skilled in the art that a variety of modifications and variations may be made to the present invention without departing from the spirit or scope of the present invention defined in the appended claims and their equivalents.

What is claimed is:

1. A display device, comprising:
a substrate having a red sub-pixel region, a green sub-pixel region and a blue sub-pixel region;
a red color changing layer located on the red, green and blue sub-pixel regions, the red color changing layer changing a color of a portion of light passing through the red sub-pixel region to red and having a first opening formed in the green sub-pixel region and a second opening formed in the blue sub-pixel region;
a green color changing layer located in the first opening, the green color changing layer changing a color of a portion of the light passing through the green sub-pixel region to green; and
a blue color changing layer located in the second opening, the blue color changing layer changing a color of a portion of the light passing through the blue sub-pixel region to blue.

2. The display device according to claim 1, wherein each of the red, green and blue sub-pixel regions has a light extraction region and a transistor region having a transistor.

3. The display device according to claim 2, wherein, in each of the red, green and blue sub-pixel regions, the red color changing layer covers the transistor.

4. The display device according to claim 2, wherein:
the first opening is located in the light extraction region of the green sub-pixel region, and
the second opening is located in the light extraction region of the blue sub-pixel region.

5. The display device according to claim 2, wherein, in each of the red, green and blue sub-pixel regions:
the transistor comprises: a semiconductor layer located on the transistor region; a gate insulating layer located on the semiconductor layer; and a gate electrode located on the gate insulating layer, and
the red color changing layer covers the gate electrode.

6. The display device according to claim 5, in each of the red, green and blue sub-pixel regions, the transistor further comprises source and drain electrodes connected with source and drain regions of the semiconductor layer and extending through the red color changing layer and the gate insulating layer, and the red color changing layer insulates the source and drain electrodes from the gate electrode.

7. The display device according to claim 2, wherein each of the red, green and blue sub-pixel regions further comprises a capacitor region having a capacitor.

8. The display device according to claim 7, wherein, in each of the red, green and blue sub-pixel regions:
the transistor further comprises: a semiconductor layer located on the transistor region; a gate insulating layer located on the semiconductor layer; and a gate electrode located on the gate insulating layer,
the red color changing layer covers the gate electrode,
the capacitor comprises a first capacitor electrode formed on a same layer as the semiconductor layer, and a second capacitor electrode formed in the capacitor region of each sub-pixel region and on a same layer as the gate electrode, and
the gate insulating layer is interposed between the first capacitor electrode and the second capacitor electrode.

9. The display device according to claim 8, in each of the red, green and blue sub-pixel regions, the transistor further comprises source and drain electrodes connected with source and drain regions of the semiconductor layer and extending through the red color changing layer and the gate insulating layer,
wherein the capacitor further comprises a third capacitor electrode formed on a same layer as the source and drain electrodes, and the red color changing layer is interposed between the second capacitor electrode and the third capacitor electrode.

10. The display device according to claim 8, wherein the second capacitor electrode is extended to a predetermined region of the light extraction region of each sub-pixel region to block the portion of the light passing through the light extraction region of each sub-pixel region.

11. The display device according to claim 2, further comprising:
first electrodes located on the corresponding light extraction regions of the red color changing layer of the red sub-pixel region, the green color changing layer of the green sub-pixel region, and the blue color changing layer of the blue sub-pixel region;
a pixel defining layer having, for each first electrode, an opening exposing a part of a surface of the first electrode;
an emission layer formed on each of the exposed first electrodes; and
a second electrode formed on the emission layer.

12. The display device according to claim 11, wherein the emission layer emits a single color of light.

13. The display device according to claim 11, wherein the single color of light is white or blue light.

14. The display device according to claim 11, wherein each of the first electrodes comprises indium tin oxide or indium zinc oxide.

15. The display device according to claim 11, wherein the second electrode comprises at least one material selected from the group consisting of magnesium, calcium, aluminum, silver, and alloys thereof.

16. The display device according to claim 1, wherein each of the red, green and blue color filter layers is formed to a thickness of about 0.1 μm to about 2.5 μm.

17. The display device according to claim 1, wherein each of the red, green and blue color filter layers includes an acrylic resin, a pigment and a polymer binder.

18. A display device, comprising:
a light emitter which emits a light;
a substrate having a first color sub-pixel region through which a first light portion of the light passes, and a second color sub-pixel region through which a second light portion of the light passes;
a first color layer located on the first and second color sub-pixel regions, the first color layer changing a color of the first light portion to a first color and having a first opening formed in the second color sub-pixel region; and
a second color layer located in the first opening, the second color layer changing a color of the second light portion to a second color other than the first color.

19. The display device of claim 18, further comprising gate, source, and drain electrodes in the second color sub-pixel region, wherein the first color layer electrically insulates the gate electrode from the source and drain electrodes.

20. The display device of claim 18, wherein the first color layer comprises a first color filter layer which includes a support, a pigment of the first color, and a polymer binder.

21. The display device of claim 18, wherein the first color layer comprises a first color conversion layer which includes a fluorescent material and a polymer binder.

22. A method of forming a display device, the method comprising:
forming a first color layer on a substrate having a first sub-pixel region and a second sub-pixel region, the formed first color layer covering a light extraction region of each of the first and second sub-pixel regions;
etching an opening in the formed first color layer at the light extraction region in the second sub-pixel region; and
filling a second color layer in the opening etched into the formed first color layer, the second color layer changing a color of light to a second color for a portion of light passing through the second sub-pixel region while the first color layer of the first sub-pixel area changes a color of the light to a first color for a portion of the light passing through the first sub-pixel region.

23. The method of claim 22, the forming the first color layer further comprises forming the first color layer to cover, in each of the first and second sub-pixel regions, a gate electrode located above source and drain regions of a semiconductor layer.

24. The method of claim 23, further comprising forming, in each of the first and second sub-pixel regions,
a source electrode on the formed first color layer and which is connected to the source region of the semiconductor layer while being electrically insulated from the gate electrode by the formed first color layer, and
a drain electrode on the formed first color layer and which is connected to the drain region of the semiconductor layer while being electrically insulated from the gate electrode by the formed first color layer.

25. The method of claim 23, wherein the formed first color layer comprises a first color filter layer which includes a support, a pigment of the first color, and a polymer binder.

26. The method of claim 23, wherein the formed first color layer comprises a first color conversion layer which includes a fluorescent material and a polymer binder.

27. The method of claim 23, further comprising:
etching contact holes in the formed first color layer to expose, in each of the first and second sub-pixel regions, the source and drain regions of the semiconductor layer, and
forming, in each of the first and second sub-pixel regions, a source electrode on the formed first color layer and which is connected to the source region through a corresponding one of the etched contact holes while being electrically insulated from the gate electrode by the formed first color layer, and a drain electrode on the formed first color layer and which is connected to the drain region through a corresponding other one of the etched contact holes while being electrically insulated from the gate electrode by the formed first color layer.

28. The method of claim 27, further comprising:
forming a first electrode on the formed first color layer covering the light extraction region of the first sub-pixel region and which is electrically connected to the source electrode of the first sub-pixel region;
forming another first electrode on the formed second color layer covering the light extraction region of the second sub-pixel region and which is electrically connected to the source electrode of the second sub-pixel region;
forming a pixel defining layer covering, in each of the first and second sub-pixel regions, the source and drain electrodes without covering the light extraction region;
forming an emission layer on the formed pixel defining layer and, in each of the first and second sub-pixel regions, the light extraction region; and
forming a second electrode covering the formed emission layer.

29. The method of claim 28, wherein:
the forming the first color layer further comprises covering a capacitor electrode in a capacitor region of each of the first and second sub-pixel regions,
the forming the source and drain electrode further comprises forming, in the capacitor region of each of the first and second sub-pixel regions, another capacitor electrode on the formed first color layer, and
the forming the pixel defining layer further comprises the pixel defining layer covering, in each of the first and second sub-pixel regions, the formed another capacitor electrode.

30. The method of claim 29, further comprising forming the capacitor electrode to be in the light extraction region of the one first and second sub-pixel regions and in the capacitor region of the other one of the first and second sub-pixel regions.
